(19) United States
(12) Patent Application Publication
(10) Pub. No.: US 2019/0108195 A1
(43) Pub. Date: Apr. 11, 2019

(54) ELECTRONIC COMPRESSION FILTER FOR POLLING DATA

(71) Applicant: Michael Dale Nelson, Pleasanton, CA (US)

(72) Inventor: Michael Dale Nelson, Pleasanton, CA (US)

(21) Appl. No.: 15/730,630

(22) Filed: Oct. 11, 2017

(51) Int. Cl. G06F 17/18; G06F 17/30; G06F 3/06; H03M 7/30

(52) U.S. Cl. CPC G06F 17/18; H03M 7/3059; G06F 3/0643; G06F 17/30

(57) ABSTRACT

An electronic compression filter is designed capable of locating unnecessary data in polling data. A statistical based polling error analysis using past polling data and past voting data from multiple geographic regions, converting these error signals into filtered occurrence frequencies associated with various standard deviation intervals, assigning priority codes to repeating geographic regions and then compressing these signals. The purpose is to reduce the amount of polling data to be processed, but application of the compression filter to upcoming polling data can predict the winner of the upcoming election.

### BACKGROUND OF THE INVENTION

Compression and filtering technology has been applied to many facets of the computer processing, application, data storage, and electronic file and signal transmission, including, networking and the internet. It is so interwoven into the fabric of the computer that most operations would cease to perform or perform at exceedingly slow speeds. Most people know about compression as it relates to reducing file sizes associated with images, music, and movies. See U.S. Pat. Nos. 4,698,672, 4,467,495, 4,302,775, 5,287,420, 6,657,565. But compression and filtering technology has also been applied to databases, transmission of digital signals over the internet, and increasing computer processing efficiency and speed. See for example, U.S. Pat. Nos. 4,988,998 and 7,190,284.

Most of the compression and filtering methods are directed to avoiding or disregarding duplicative or unnecessary data. But finding this duplicative or unnecessary data is often exceptionally difficult, and compressing and decompressing the data are frequently challenging. Finding the unnecessary and duplicate information in data files or streams, can range from the easy, such as eliminating redundant or unnecessary words, pixels, etc to exceptionally difficult, such as finding data or signals that vary with each scan, application, or manipulation.

Polling data is one of the most complicated to search because of the existence of highly variable and spontaneous temporal factors, e.g. human factors. These human factors change from person to person, pollster to pollster, occurrence to occurrence, and day to day. Identifying these human factors are difficult, but quantifying them have been essentially impossible. Attempts to search data for these human factors, i.e. pollster bias, non-response, honesty, understanding, intimidation, media influences, etc. and then applying those factors the polling data have had the opposite effect. For example, attempts to quantify bias, and then applying a bias factor to the polling data resulted in larger file sizes and longer processing times.

The present invention is directed to filtering and compressing polling data based on a statistical methodology using past polling errors. This analysis is not based on successes, i.e. who won or did better, but on the amount of error deviations between polling regions. Using this methodology, it was discovered that the number of geographic polling regions could be dramatically reduced. With this method, it was believed that the error deviations observed in these limited number of geographic polling regions could be extrapolated to the other regions and reduce the amount of unnecessary error data included in the files. It was believed that by removing this error data the file size could be reduced and the processing efficiency could be improved. However, when these electronic compression filter signals were applied to the current polling data from states in a national presidential election, it was discovered that they exhibited a totally unexpected side effect. The processed current polling data exhibited a direct relationship with the winner in the upcoming election. Testing this observation from numerous past elections showed that the relationship had an astounding accuracy. How this electronic compression filter produces signals capable of predicting the outcome of an election that has not occurred remains unknown.

### SUMMARY OF THE INVENTION

The object of this invention is to provide an electronic compression filter capable of locating and disregards unnecessary polling data. The best use of this electronic compression filter is for state election polling data from the candidates of the top two political parties in US presidential elections. However, it is also applicable to other polling circumstances such as state elections or foreign national elections with various geographical voting regions. A statistical based polling error analysis is used to control and manage the logic circuits of a digital computer to locate the unnecessary data. Past polling data are compared to past voting data to determine the polling errors for each geographic region for at least one prior election period. The resulting polling errors are converted into occurrence frequencies via an algorism associated with various standard deviation intervals. The occurrence frequency values for either a zero standard deviation, or a very narrow range of standard deviations around the zero value, must maintain a relationship with each geographic region or state. When repeating geographic regions or states appear they are assigned priority codes. The priority codes are controlled by a compression selection that turns on or off those signals complying or not complying with the settings. In a preferred embodiment, the compression filter signals relate to those states or regions having only the higher priority codes. At this point reports can be generated from the compression filter signals that identifies those geographic regions fitting the selected filter and compression settings.

When the compression filter signals are used to process the incoming current polling data, projection signals are produced that relate to the probable winner of the upcoming election. This compresses the polling data from 50 to 90 percent. A surprising outcome in using this compression and filtering system was that this highly filtered and compressed signals could be used to predict the winner of an upcoming election with an amazing 98% accuracy.

### BRIEF DESCRIPTION OF THE DRAWINGS

FIG. 1 depicts the general flowchart for compression and filtering of the polling data.

FIG. 2 depicts the flowchart for the generation of the occurrence event signals.

FIG. 3 depicts a plot for an exemplary occurrence event signals.

FIG. 4 depicts the flowchart for the generation of the occurrence frequency signals.

FIG. 5 depicts a plot for an exemplary occurrence frequency signals.

FIG. 6 depicts the flowchart for the generation of the compression filter signals.

FIG. 7 depicts a plot for an exemplary compression filter signals.

FIG. 8 depicts an exemplary compression filter report for a sample filter and compression setting for single election year periods and the Standard Deviation Interval rounded to a Whole integer.

FIG. 9 depicts an exemplary compression filter report for a sample filter and compression setting for two consecutive election year periods and the Standard Deviation Interval rounded to a Half integer with a priority code equal to 4.

FIG. 10 depicts an exemplary compression filter report for a sample filter and compression setting for single election year periods and the Standard Deviation Interval rounded to a Half integer.

FIG. 11 depicts an exemplary compression filter report for a sample filter and compression setting for two consecutive election year periods and the Standard Deviation Interval rounded to a Whole integer with a priority code equal to 3 and 4.

FIG. 12 depicts a table showing the success of the compression filter in predicting the winner in the following election.

### DETAILED DESCRIPTION

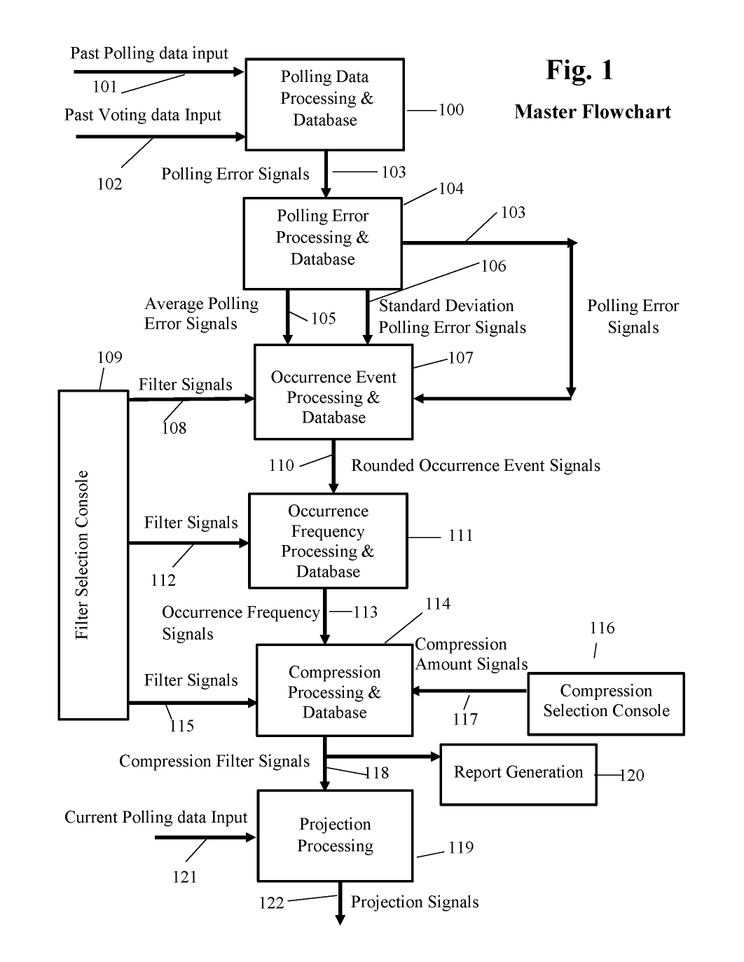

The general flowchart for the design of an electronic compression filter is shown in FIG. 1. The best embodiment of this invention relates to compressing and filtering polling and vote data from the States applicable to the candidates from the top two political parties for a national presidential election. This embodiment is discussed in detail herein to make the disclosure easier to follow and understand. However, the usefulness of this invention can be applied to other polling embodiments as discussed hereinafter and in the section on Other Polling Applications.

This device and method can scan, find, and filter-out unnecessary polling data at varying compression levels. This electronic filter improves the selection and computer processing and/or transmission of polling data. A statistical polling error analysis directs the logic circuits via specifically controlled sequences to locate the unnecessary data. This sequence starts with inputting two different data digital signals into a relational database 100 within a digital computer system. One type of data signals are past polling data 101 and the other are pass success, e.g. voting, data 102 relating to the polling data. Both of these signals are digitally correlated to percentages.

In a preferred embodiment the data are collected from one or more prior polling or election periods. The two data files and/or signals are associated with the same political parties, election years and geographic regions. The two data signals are compared, i.e. the polling data signals are subtracted from the success or voting data signals to determine the polling accuracy or polling error for each region or state. This does not depend upon who or what was more successful, but only on the amount of error deviation between the poll and success, e.g. vote.

The polling error (PE) signals 103 are generated; and the polling error data are stored in a database 104, which are filed in the same database 100 as referenced above. But, a different database could be used as long as the data relationships are maintained. An average polling error (APE) signals 105 and a standard deviation polling error (SDPE) signals 106 are calculated by standard methods for each candidate from the Democrat and Republican parties over each of the 50 states, and for each election year. Reference to candidate means the nominees from the two parties in the US or multiple parties in foreign elections. Occurrence event (OE) signals are generated in accordance with the following algorism:

OE=(PE−APE)/SDPE

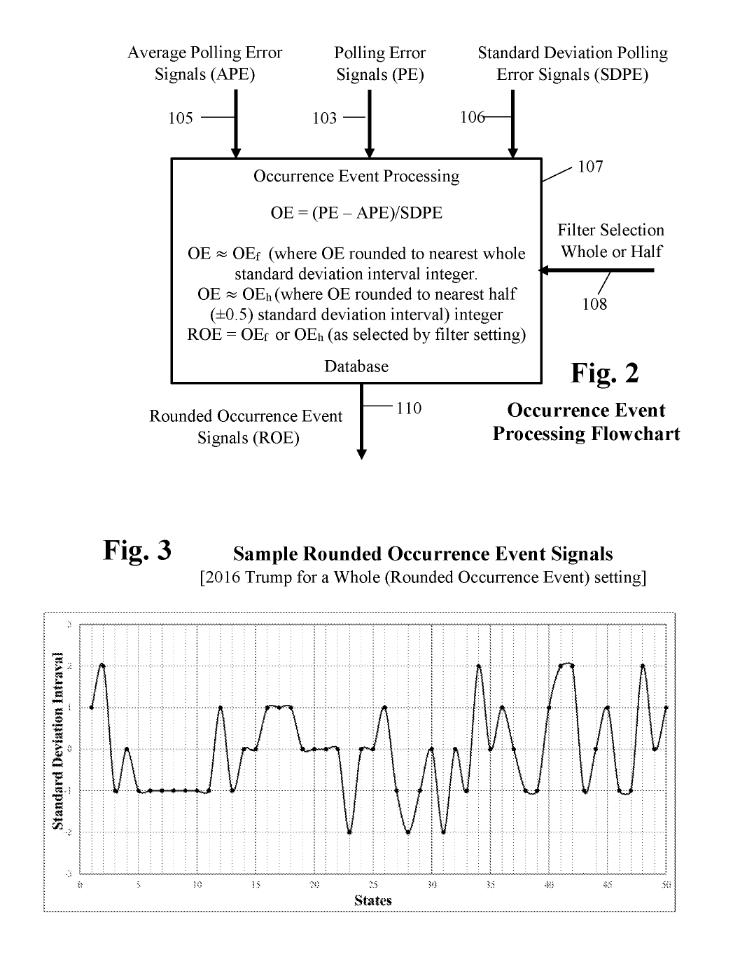

These occurrence event (OE) signals are shown in the Occurrence Event Flowchart and Database 107 in FIG. 1 and FIG. 2. These OE signals maintain a relationship with the candidates, election years and states. The occurrence event data values are rounded to the nearest standard deviation interval. Under the preferred embodiment, there are two different rounding values—Whole, i.e. rounded to the nearest whole integer and Half, i.e. rounded to the nearest half (0.5 or ½) integer. The rounding selection may be accomplished by the operator via the filter selection console 109 with filter signals 108. The Whole occurrence event rounding is where the signals are rounded to the nearest whole integer, i.e. 0, 1, −1, 2, −2, 3, −3, 4, −4 . . . to “n” numbers. The Half occurrence event rounding is where the occurrence event is rounded to the nearest half integer, i.e. 0, 0.5, −0.5, 1, −1, 1.5. −1.5, 2, −2, . . . to “n” numbers. References to “Whole” and “Half” settings made hereinafter and in the Figures, are referring to the aforesaid occurrence event rounding discussed above.

Rounding for both the Whole and Half integer are to the nearest higher or lower value, that is, it can be less or more than the value to be rounded. For example, in a Whole rounding, a standard deviation interval of 1.45 is rounded to 1, and a standard deviation interval of −1.65 is rounded to −2. A standard deviation interval of +0.38 is rounded to 0 and −0.28 is also rounded to 0. In a Half rounding, a standard deviation interval of 1.45 is rounded to 1.5, and a standard deviation interval of −1.30 is rounded to −1.5. A standard deviation interval of +0.38 is rounded to 0.5 and −0.23 is rounded to 0.

When the Whole rounding is selected there are several standard deviation interval values that can be use, but the recommended value is 0. Using ±1 in addition to 0 would likely result in too many states being included within the compression filter signals.

When the Half rounding is selected there are multiple standard deviation interval values that can be used. In a preferred embodiment, only a 0 standard deviation value is used. Another embodiment would be using a 0 standard deviation value plus a −0.5 standard deviation value. A third embodiment would be to use a 0 standard deviation value plus a +0.5 standard deviation value. A fourth embodiment would be to use a 0 standard deviation value plus a −0.5 value plus a +0.5 value (as used herein a ±0.5 designation herein means both i.e. a +0.5 and a −0.5). Selecting values beyond ±0.5 are not recommended since it would normally produce too many states to be included in the compression filter signals. The 0 standard deviation value is included in all of the selections in the Whole and Half roundings. The rounded occurrence event (ROE) signals 110 are shown in FIG. 1 and FIG. 2.

Sample rounded occurrence event signals 110 are shown in FIG. 3. The raw data used in FIGS. 3, 5, 7 and 8-12 are set forth in Tables A and B. FIG. 3 illustrates a plot of the rounded occurrence event signals using the Whole setting for the 2016 election applicable to candidate Donald Trump. The X axis in FIG. 3 is a number from 1 through 50 representing the 50 states in alphabetical order. This particular plot shows that the standard deviation interval values varied from a −2 to a +2. Other sample plots for other candidates, periods, and rounded Whole or Half values may have higher and/or lower values. However, most of the standard deviation interval values for both the Whole and Half rounding are constrained between −3 and +3.

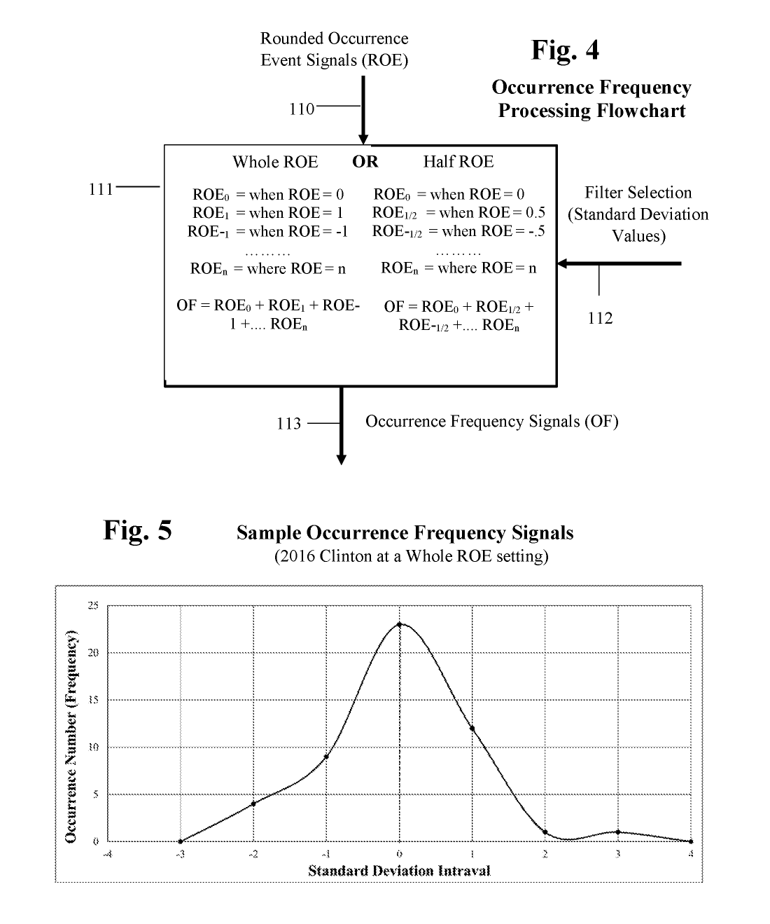

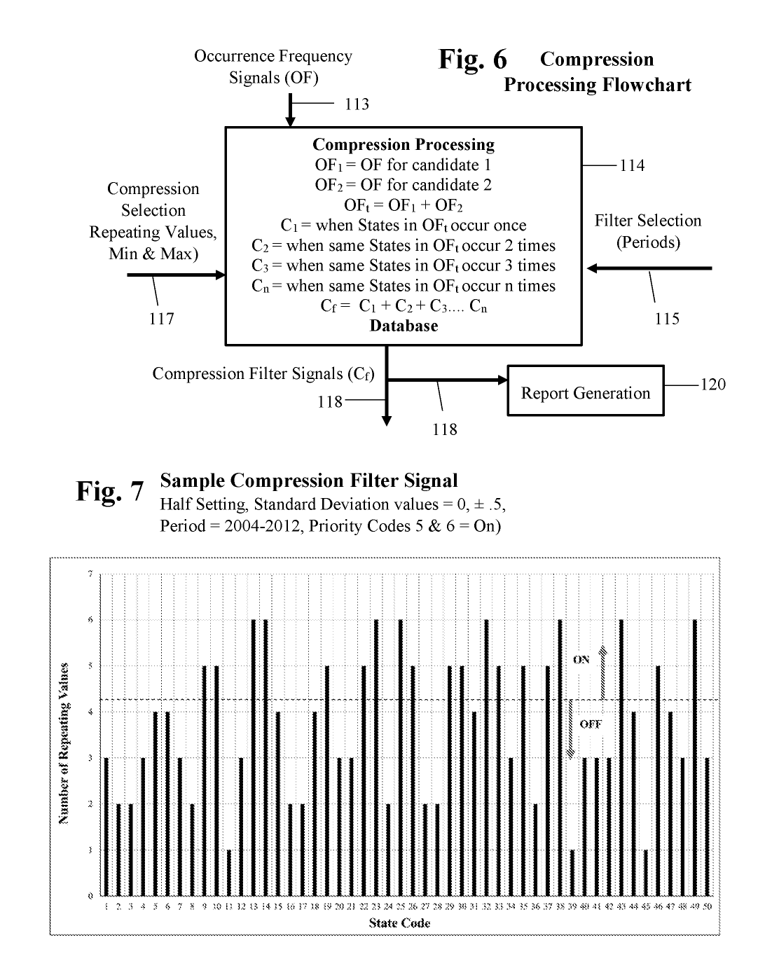

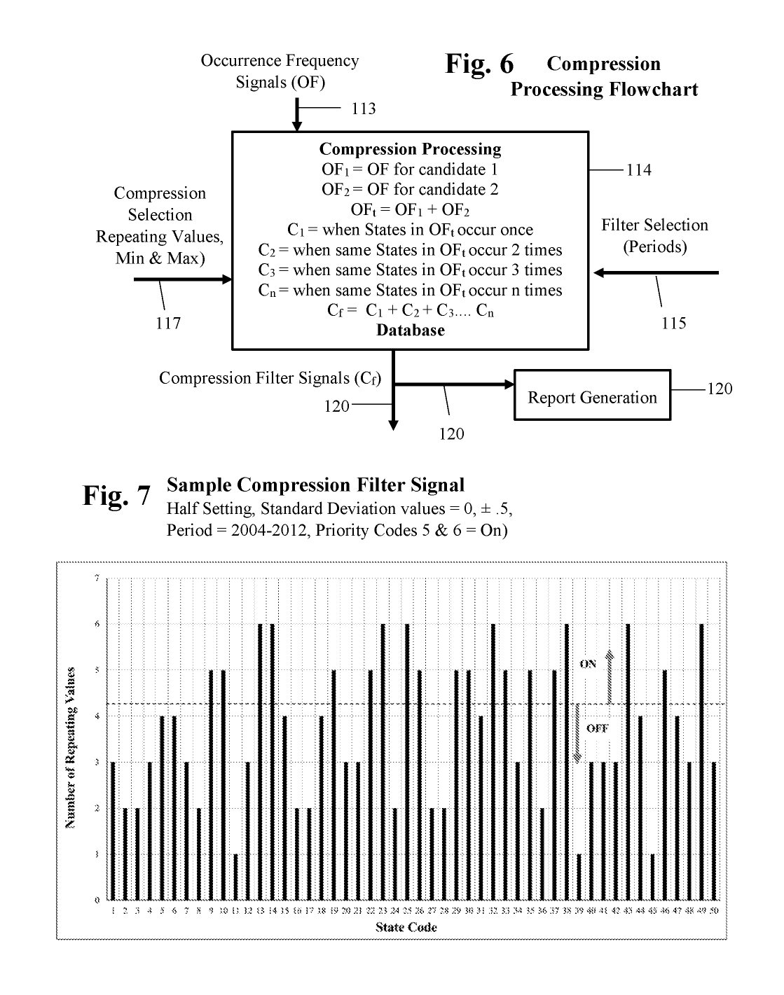

The rounded occurrence event (ROE) signals 110 are further processed as shown in the FIG. 1 and FIG. 4 and represented in the Occurrence Frequency Processing Flowchart and Database 111. Here, the number of geographic regions or states having the same value are summed. For example, if the Whole rounding is selected, then the number of states having a 0 standard deviation value are reflected in signals 113. For purposes of illustration to show how the occurrence frequency signals follows the typical bell-shaped curves used in statistics, the numbers for other standard deviation values are also summed, i.e. those states having a −1 standard deviation interval are counted, the number of states having a +1 standard deviation interval are counted, and so forth for all other standard deviation intervals. If the Half rounding is selected, then the number of states having a 0 standard deviation value are counted in signals 113. In another embodiment, those states having a −0.5 standard deviation interval are also counted. In a third embodiment those states having a +0.5 standard deviation interval is additionally counted. In a preferred fourth embodiment those states having a standard deviation of 0 plus having a standard deviation of −0.5 plus having a standard deviation of +0.5 are counted. Other standard deviation values above 0.5 and below −0.5 can be counted but may result in too many states being identified, i.e. above 35. The occurrence frequency (OF) signals 113 for each Whole and Half rounding, for each standard deviation value, for each candidate and for each period, and may be filed and stored in relational database 111.

Sample occurrence frequency (OF) signals 113 are shown in FIG. 5. This figure is a plot of the occurrence frequency (OF) signals 113 for the 2016 election applicable to Hillary Clinton with a Whole rounding. The standard deviation value of “0” was selected via filter signals 112 from Filter Selection Console 109. The X axis in FIG. 5 is the Standard Deviation Intervals values from −4 to +4. The occurrence frequency values are plotted on the Y axis. The occurrence frequency values represent the number (frequency) of states that have the same standard deviation interval integer value. For example, the peak of the curve in FIG. 5 occurs at the number 23. This number represents the number of states in the 2016 election period for Hillary Clinton that had a zero standard deviation value using a Whole rounding. The identity of each state within each interval may be stored in the relational database 111. Although the standard deviation interval values other than 0 are not typically used in a Whole rounding, FIG. 5 displays multiple standard deviation interval values to illustrate the bell-shaped curve appearance of the data points. This is the same type of bell-shaped curve used in statistics and referred to as a normal or gaussian distribution.

The occurrence frequency (OF) signals 113 are further processed in the compression filter Processing 114. The occurrence frequency signals 113 are for a selected Whole or Half rounding, and applicable to each candidate for each period, or multiple periods, and for a standard deviation interval value or range of values. The identity of the specific candidate is not important since it changes from election to election. It is the Political Parties, i.e. Democrat or Republican, that is important. These OF signals maintain its relationship with the variables, i.e. states, candidates, periods, standard deviation intervals, etc. and are usually stored in a relational database. When a specific standard deviation interval value or values is/are selected by the filter signals 112 from the Filter Selection Console 109, then those states included within that/those numbers are identifiable for each candidate for each period. The states included within each interval number for the selected standard deviation value for each candidate are combined for each period. For example, if one Democrat candidate had 8 states with a 0 standard deviation value and the Republican candidate had 23 states with that same 0 standard deviation value, then those states from both candidates are combined. If there were more than two major political parties, then the states or geographic areas applicable to all of the political party candidates would be combined. If the states applicable to each candidate are not combined in a single period situation, there would be no repeating states. This would reduce the accuracy of the results as well as increase the number of state polling data that would have to be processed. The multi-period situations would result in repeating states without combining the candidate states. However, in the preferred mode, the states applicable to each candidate are also combined in the in the multi-period circumstances.

In this preferred embodiment, signals 113 represent the combined candidates' states. It is recognized that some of those states will be duplicated, i.e. occurs more than once. Each state is assigned a priority code associated with the number of times the state is repeated. States that appear, i.e. occur once, in the signals are assigned a priority code of 1. States that appear or occur twice, i.e. duplicated, are assigned a priority code of 2, states occurring 3 times are assigned a priority code of 3 and so forth for n number of repetitions in accordance with the equation below.

C_{f}=C₁+C₂+ . . . Cₙ

In this equation, C₁ represents the states in signals 113 with a priority code of 1, i.e. appear in the signals but not duplicated; C₂ represents the states with a priority code of 2; C₃ represents the states with a priority code of 3; and so forth for up to “n” priority codes. C_{f} is the compression filter signals 118 representing all the states contained in C₁+C₂+ . . . . Cₙ. C_{f} is the signals that relates to the sum of the states from the candidates from both political parties with an assigned priority code. These data signals are preferably stored in a relational database 114. There will be no identical states with the same priority code in signals C_{f} but only states with various assigned priority codes. For example, there will not be a state, such as Kansas, listed more than once even if Kansas appeared multiple times before the priority codes were applied.

The amount of compression may be selected by the operator via the compression amount signals 117 from the Compression Selection Console 116, or it could be automatically given various default values. The compression magnitude will affect the number of states listed in the compression filter signals 118. The higher the selected compression the fewer the states that will be included. In a preferred embodiment, the amount of compression should be selected so that the number of states included in the signals 118 are greater than five, and more preferably greater than 7, for a particular period or multiple periods. It is preferred that the number of states be an odd number to avoid ties, particularly if the total number of states are 10 or less. On the other hand, a low compression may result in a large number of states. A high number of states increases the work load on the computer processor and diminishes the underlying purpose of this invention. It is preferred that the number of states in signals 118 be less than 35 and more preferably 25 or less. The compression filter signals 118 with a selected priority code or range of priority codes that is/are set to the ON state will allow those signals containing states with that priority code to passes through to Projection Processing 119 and/or Report Generation 120. The compression filter signals 118 with priority codes below the selected value or values will be set to an OFF state and will be blocked or not used.

A sample compression filter (C_{f}) signals 118 is shown in FIG. 7. This figure is a plot of the compression filter C_{f} signals for a multiple period of 2004, 2008 and 2012 (three election periods) filtered to a Half rounding, and further filtered to a standard deviation range of 0 plus −0.5 plus+0.5. The dotted line in FIG. 7 represents a sample compression setting to states having a priority code of 5 and 6.

Compression filter signals 118 pass into Projection Processing 119 and regulates the current polling input signals 121 so that only those signals with the selected priority codes are further processed and those signals 121 that do not have the requisite priority codes are blocked.

In the Projection Processing 119 the incoming current polling data signals that are allowed to proceed are related to each candidate and are further related to each Political Party's polling percentages. Those signals associated with the candidates receiving the highest polling percentage from each state that had the applicable priority codes are summed and compared. The candidate having the highest polling percentage from the most filtered and compressed states represents the projected winner. If both candidate's each win the same number of states, then the projection signals 122 will show that a tie had occurred. As an illustration, if there are 10 states in the current polling data signals that are allowed to pass through, and candidate A has the highest polling percentage in 8 of those states and candidate B has the highest polling percentage in 2 of those states, then the projected winner will be candidate A and will be reflected in signals 122. If both candidates each win 5 states, then signals 122 will indicate a tie status.

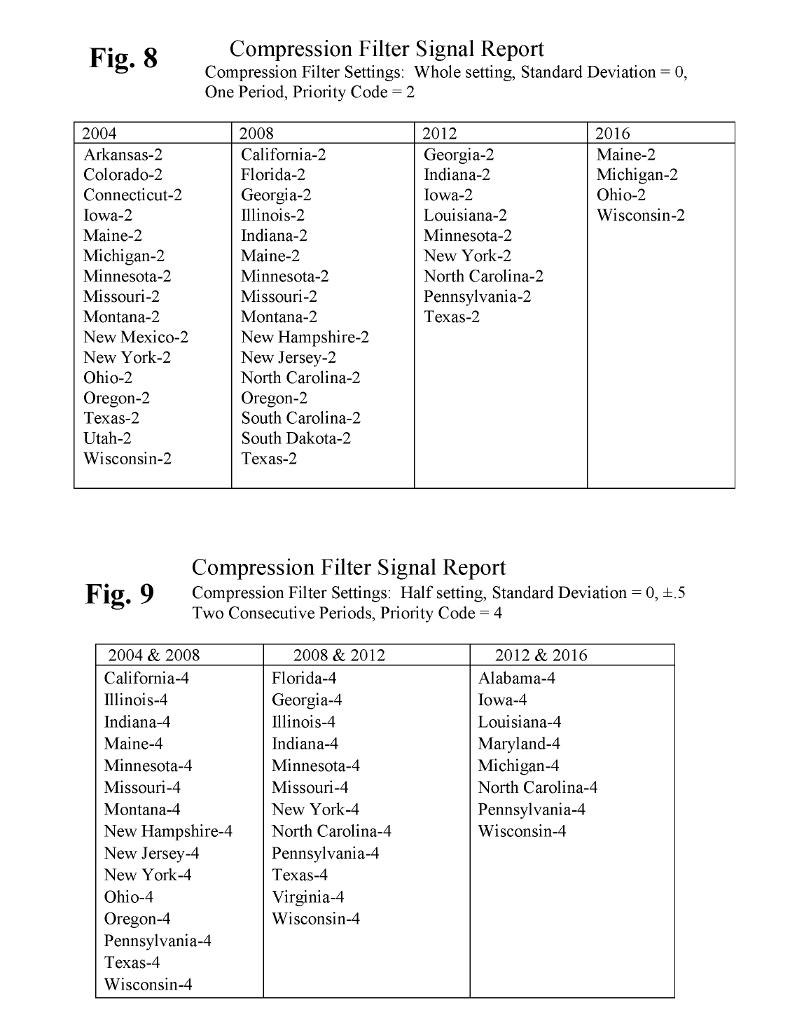

The compression filter signal report 120 has value in and of itself. The report identifies those states that would be necessary to compute the projected winner and those states that can be removed from consideration. These compression and filtering manipulations reduces the time, effort, and cost of conducing polls in those states found “unnecessary”. Representative compression filter reports are set forth in FIGS. 8 through 11. These figures are working examples using the actual polling error data generated from previous election periods.

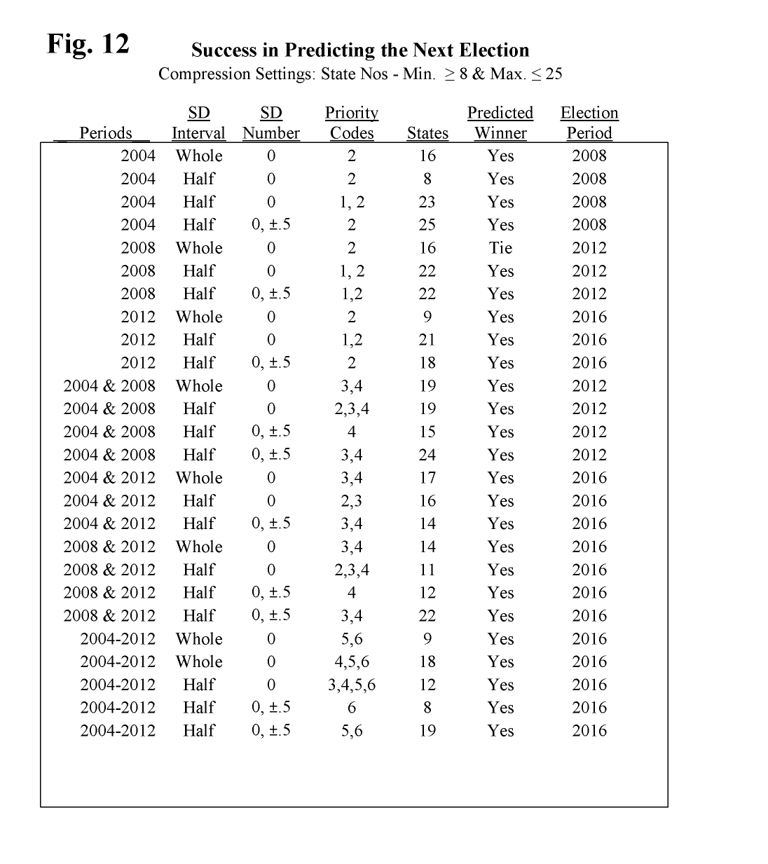

FIG. 8 illustrates a compression filter Report with the specified settings as set forth in the figure. This report shows the compressed and filtered states for each of the single election years 2004, 2008, 2012 and 2016. For the 2004 election year there were 16 states identified ranging from Arkansas to Wisconsin. With this compression and filtering settings and using the polling data for 2008, the projection signals 122 would forecast Obama as the winner in following 2008 election. The 2008 polling data is used and not the voting data since the latter would not exist until after the election. The projection successes of the compression filter are shown in FIG. 12. For example, in 2008 there were 16 states identified ranging from California to Texas. Using the 2008 compressed and filtered data and processed with the polling data for 2012, Obama would be the projected winner in 2012 election. For 2012 there were 9 states identified ranging from Georgia to Texas. With the 2012 data and processed with the polling data for 2016, it would project Trump as the winner in 2016.

The multiple year data shown in FIG. 9 shows a compression filter Report for multiple years. For example, for the combined 2004 & 2008 multiple year data there are 15 states listed from California to Wisconsin and each state was repeated or appeared 4 times. This is because the half standard deviation interval with a range of standard deviation values and from two years produced more multiple repeating states than using single year data. The 2004 & 2008 multiple year data correctly predicted Obama's victory over Romney in 2012. The 2008 and 2012 multiple year data in FIG. 9 shows 12 states ranging from Florida to Wisconsin. It corrected predicted Trump's victory over Clinton. The 2012 & 2016 multiple year period shows 8 states ranging from Alabama to Wisconsin. It will be the polling data from these 8 states that will be used to project the winner of the 2020 election.

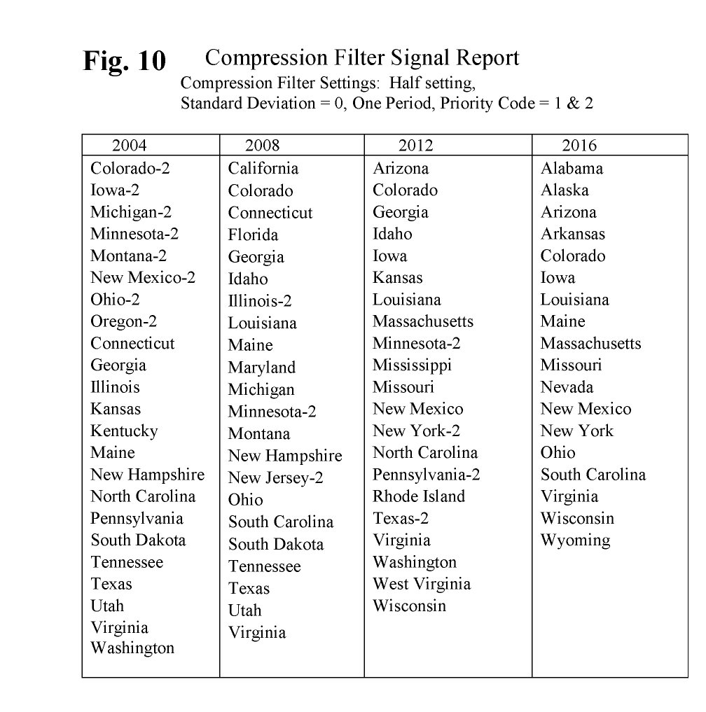

FIG. 10 illustrates a compression filter Report with the with the specified settings. This report shows the compressed and filtered signals for the single election periods of 2004, 2008, 2012 and 2016. The 2004 compression filter data report lists 23 states ranging from Colorado to Washington. Using these 23 states with the polling data for 2008 it correctly projected Obama over McCain in 2008. This is shown in the Success Table in FIG. 12. For 2008 there were 22 states identified ranging from California to Virginia. Using this 2008 data and processed with the polling data for 2012, it correctly projected Obama as the winner in 2012. For 2012 there were 21 states identified in the compression filter report ranging from Arizona to Wisconsin. With this 2012 data and processed with the pre-election polling data for 2016, Trump was the projected the winner. The 2016 data showed 18 states from Alabama to Wyoming. It will be the polling data from these 18 states that will be used to project the winner of the 2020 election.

The compression priority in FIG. 10 was set to 1 and 2 while the compression priority setting shown in FIG. 8 was 2. This modification was because a filter setting of “Half” in FIG. 10 and using a standard deviation value=0, resulted in too few states with priority codes=2. For example, the number of states with a priority code of 2 were 8 for 2004, 3 for 2008, 4 for 2012 and 0 for 2016. The 2004 value of 8 would be sufficient, and it correctly projected the winner of the 2008 election, but the values of 3 for 2008, 4 for 2012, and 0 for 2016 are too few.

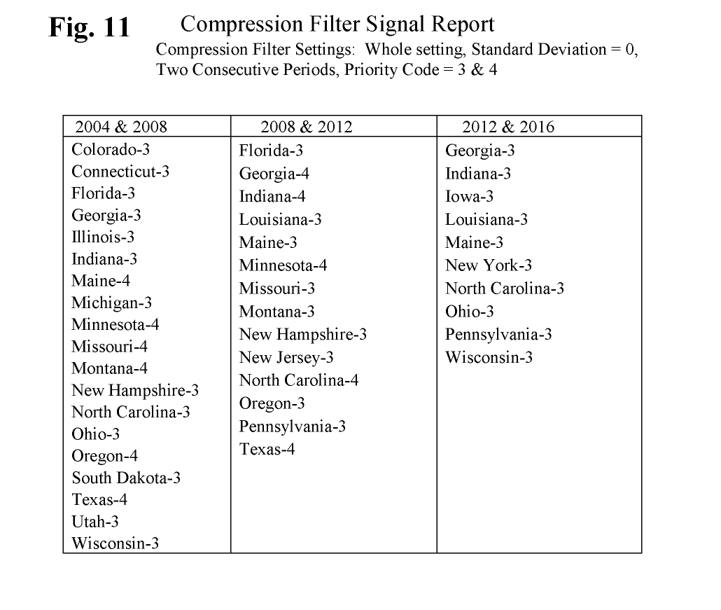

FIG. 11 illustrates a compression filter Report using the specified settings. This report shows the compressed and filtered signals for two consecutive election years, i.e. 2004 & 2008, 2008 & 2012, and 2012 & 2016. The 2004 & 2008 compression filter data report lists 19 states ranging from Colorado to Wisconsin. Using these 19 states with the polling data for 2012 it correctly projected Obama over Romney in 2012. This is shown in the Success Table in FIG. 12. For 2008 & 2012 data there were 14 states identified ranging from Florida to Texas. Using this 2008 & 2012 data and processed with the polling data for 2016, correctly projected Trump as the winner in 2016.

The multiple year data shown in FIG. 11 at a whole setting is not the same as simply combining the two single years shown in FIG. 8 using a Whole integer setting. For example, in FIG. 11 the 2004 & 2008 data as compared to combined individual 2004 and 2008 data shown in FIG. 8, illustrates that many states were dropped, i.e. Arkansas, Iowa, New Mexico, New York, California, New Jersey, and South Carolina. However, both sets of data with different states each correctly predicted the winner in the next election in 2012. The same occurred for the 2008 & 2012 data compared with the 2008 and 2012 individual data. Different states in one set of data still predicted the correct winner in the following election year. These projections were obtained from the polling error data and not from any after-the-fact judgment decision. The actual data produced the states in the compression filter. This data, not judgment calls, unexpectedly and accurately predicted the winner that occurred in the following elections. These correct predictions also occurred when different compression and filter settings were used and even when such settings resulted in different states being identified by the compression filter.

The success in predicting the winner in the following or next election is shown in FIG. 12 for various filter setting and for various compression settings. The compression settings selected were for a minimum of 8 and maximum of 25 states. This Figure illustrates the accuracy in the predictions using data not judgments or the application of hindsight. This accuracy is almost 100% with the exception of a tie prediction in the 2012 election using a selected compression and filter settings and 2008 polling data. This Figure demonstrates a 98% success rate (25 correct predictions, 1 tie and 0 incorrect predictions). The Figure further shows that in the event of a tie, slightly different filter or compression settings would reveal multiple correct predictions.

Almost all of the polls in the 2016 election failed to predict Trump as the winner. The compression filter of this invention accurately projected Trump as the winner based on polling data prior to the election. The compression filter substantially reduces the number of state polls necessary to project the winner or the unnecessary processing of voluminous state polling data. The polling error methodology is seamlessly connected to the compression filter. That is, in order to find, locate and disregard unnecessary data, the digital signals must be controlled by the polling error analysis methodology.

The raw data used to test the accuracy of the compression filter signals are set forth in Tables A and B.

TABLE A
Polling and Voting Data
US Presidential Elections 2004 & 2008

| | 2004 | 2004 | 2004 | 2004 | 2008 | 2008 | 2008 | 2008 |
|---|---|---|---|---|---|---|---|---|
| State | Kerry | Kerry | Bush | Bush | Obama | Obama | McCain | McCain |
| Abbr | Poll % | Vote % | Poll % | Vote % | Poll % | Vote % | Poll % | Vote % |
| AL | 39 | 36.8 | 57 | 62.5 | 33.5 | 38.7 | 56.8 | 60.3 |
| AK | 30 | 35.4 | 57 | 61.8 | 41.3 | 37.9 | 55.8 | 59.4 |
| AZ | 41 | 44.5 | 56 | 54.9 | 45.8 | 45.1 | 49.3 | 53.6 |
| AR | 44.5 | 44.5 | 51 | 54.3 | 43 | 38.9 | 52.3 | 58.7 |
| CA | 54 | 54.6 | 43 | 44.3 | 58.7 | 61 | 34.3 | 37 |
| CO | 44.8 | 46.1 | 50 | 52.6 | 50.8 | 53.7 | 45.3 | 44.7 |
| CT | 52 | 54.3 | 42 | 44 | 55.3 | 60.6 | 36 | 38.2 |
| DE | 45 | 54.3 | 38 | 44.5 | 58.3 | 61.9 | 37.3 | 37 |
| FL | 47.6 | 47 | 48.2 | 52 | 49 | 51 | 47.2 | 48.2 |
| GA | 43 | 41.4 | 55 | 58 | 45.8 | 47 | 49.8 | 52.2 |
| HI | 43.8 | 54 | 44.7 | 45.3 | 68 | 71.9 | 27 | 26.6 |
| ID | 30 | 30.3 | 59 | 68.4 | 33.5 | 36.1 | 56.3 | 61.5 |
| IL | 54 | 54.6 | 42 | 44.7 | 59 | 61.9 | 34.3 | 36.8 |
| IN | 39 | 39.2 | 58 | 60 | 46.4 | 50 | 47.8 | 48.9 |
| IA | 47.1 | 49.1 | 47.4 | 50 | 54 | 53.9 | 38.7 | 44.4 |
| KS | 37 | 36.5 | 60 | 62.2 | 37 | 41.7 | 58 | 56.6 |
| KY | 38 | 39.7 | 59 | 59.5 | 41 | 41.2 | 54.5 | 57.4 |
| LA | 38 | 42.1 | 50 | 56.8 | 38 | 39.9 | 51 | 58.6 |
| ME | 51 | 53 | 41.5 | 45 | 54.4 | 57.7 | 38.8 | 40.4 |
| MD | 54 | 55.3 | 43 | 43.5 | 60 | 61.9 | 37 | 36.5 |
| MA | 50 | 62.1 | 36 | 36.9 | 57 | 61.8 | 35.7 | 36 |
| MI | 48.7 | 51.1 | 45.2 | 47.9 | 52.5 | 57.4 | 39 | 41 |
| MN | 48.5 | 51 | 45.3 | 47.6 | 51.6 | 54.1 | 41.8 | 43.8 |
| MS | 42 | 39.5 | 51 | 59.8 | 39.3 | 43 | 50.7 | 56.2 |
| MO | 45.3 | 46 | 49.5 | 53.3 | 47.8 | 49.3 | 48.5 | 49.4 |
| MT | 36 | 38.5 | 57 | 59.1 | 45 | 47.3 | 48.8 | 49.5 |
| NE | 32 | 32.4 | 61 | 66.3 | 37 | 41.6 | 56 | 56.5 |
| NV | 44.7 | 47.8 | 51 | 50.5 | 50.3 | 55.2 | 43.8 | 42.7 |
| NH | 48.5 | 50.3 | 47.5 | 48.9 | 52.8 | 54.1 | 42.2 | 44.5 |
| NJ | 49 | 52.7 | 42 | 46.5 | 54.5 | 57.3 | 39 | 41.7 |
| NM | 46.4 | 48.7 | 47.8 | 50.1 | 50.3 | 56.9 | 43 | 41.8 |
| NY | 57 | 57.7 | 39 | 40.5 | 62 | 62.9 | 32.3 | 36 |
| NC | 45 | 43.5 | 53 | 56.1 | 48 | 49.7 | 48.4 | 49.4 |
| ND | 35 | 35.5 | 55 | 62.8 | 46 | 44.6 | 47 | 53.3 |
| OH | 46.7 | 48.6 | 48.8 | 50.9 | 48.8 | 51.5 | 46.3 | 46.9 |
| OK | 34 | 34.4 | 64 | 65.6 | 35 | 34.4 | 59 | 65.7 |
| OR | 49.8 | 51.2 | 45 | 47.3 | 55.3 | 56.8 | 39.7 | 40.4 |
| PA | 48.2 | 50.8 | 47.3 | 48.6 | 51 | 54.5 | 43.7 | 44.2 |
| RI | 54 | 59.5 | 41 | 38.9 | 58 | 62.9 | 39 | 35.1 |
| SC | 39 | 46.2 | 57 | 58.2 | 43 | 44.9 | 53 | 53.9 |
| SD | 36 | 38.4 | 55 | 59.9 | 42 | 44.8 | 50.3 | 53.2 |
| TN | 40 | 42.5 | 58 | 56.8 | 38.8 | 41.8 | 52.8 | 56.9 |
| TX | 37 | 38.3 | 59 | 61.1 | 40.5 | 43.7 | 53.5 | 55.5 |
| UT | 24 | 26.5 | 69 | 70.9 | 32 | 34.4 | 57 | 62.6 |
| VT | 53 | 59.1 | 40 | 38.9 | 57 | 67.5 | 36 | 30.5 |
| VA | 47 | 45.2 | 51 | 53.9 | 50.2 | 52.6 | 45.8 | 46.3 |
| WA | 50.5 | 52.8 | 46 | 45.7 | 53.7 | 57.7 | 40.7 | 40.7 |
| WV | 43 | 43.2 | 51.5 | 56 | 42.4 | 42.6 | 51.4 | 55.7 |
| WI | 46.8 | 49.8 | 47.7 | 49.3 | 52.8 | 56.2 | 41.8 | 42.3 |
| WY | 29 | 29.1 | 65 | 69 | 37 | 32.5 | 58 | 64.8 |

TABLE B
Polling and Voting Data
US Presidential Elections 2012 & 2016

| | 2012 | 2012 | 2012 | 2012 | 2016 | 2016 | 2016 | 2016 |
|---|---|---|---|---|---|---|---|---|
| State | Obama | Obama | Romney | Romney | Clinton | Clinton | Trump | Trump |
| Abbr | Poll % | Vote % | Poll % | Vote % | Poll % | Vote % | Poll % | Vote % |
| AL | 37 | 38.4 | 58 | 60.7 | 31 | 34.6 | 53 | 62.9 |
| AK | 40.8 | 40.8 | 54.8 | 54.8 | 34 | 37.7 | 37 | 52.9 |
| AZ | 45 | 44.6 | 52.5 | 53.7 | 42.3 | 45.4 | 46.3 | 49.5 |
| AR | 31 | 36.9 | 58 | 60.6 | 32.8 | 33.8 | 53.2 | 60.4 |
| CA | 53.4 | 60.2 | 39.4 | 37.1 | 54.3 | 61.6 | 32 | 32.8 |
| CO | 48.8 | 51.5 | 47.3 | 46.1 | 43.3 | 47.2 | 40.4 | 44.4 |
| CT | 52.8 | 58.1 | 42 | 40.8 | 47.5 | 54.5 | 38.2 | 41.2 |
| DE | 58.6 | 58.6 | 40 | 40 | 46.5 | 53.4 | 31 | 41.9 |
| FL | 48.2 | 50 | 49.7 | 49.1 | 46.4 | 47.8 | 46.6 | 49.1 |
| GA | 43 | 45.5 | 53 | 53.3 | 44.4 | 45.6 | 49.2 | 51.3 |
| HI | 61 | 70.6 | 34 | 27.8 | 50.5 | 62.3 | 28 | 30.1 |
| ID | 27 | 32.6 | 63 | 64.5 | 26 | 27.6 | 50 | 59.2 |
| IL | 53 | 57.6 | 37 | 40.7 | 49 | 55.4 | 37.5 | 39.4 |
| IN | 42 | 43.9 | 51.5 | 54.1 | 38.3 | 37.9 | 49 | 57.2 |
| IA | 48.7 | 52 | 46.3 | 46.2 | 41.3 | 42.2 | 44.3 | 51.8 |
| KS | 35 | 38 | 52 | 59.7 | 34.6 | 36.2 | 48 | 57.2 |
| KY | 39 | 37.8 | 53 | 60.5 | 36.5 | 32.7 | 51.5 | 62.5 |
| LA | 36.5 | 40.6 | 56 | 57.8 | 35.6 | 38.4 | 48.8 | 58.1 |
| ME | 52.3 | 56.3 | 42 | 41 | 44 | 47.9 | 39.5 | 45.2 |
| MD | 56.7 | 62 | 36 | 35.9 | 60.3 | 60.5 | 26.6 | 35.3 |
| MA | 57.3 | 60.7 | 39.7 | 37.5 | 55.7 | 60.8 | 26.3 | 33.5 |
| MI | 49.5 | 54.2 | 45.5 | 44.7 | 45.4 | 47.3 | 42 | 47.6 |
| MN | 49.6 | 52.7 | 44.4 | 45 | 39.6 | 46.9 | 45.8 | 45.4 |
| MS | 36 | 43.8 | 54 | 55.3 | 41 | 39.7 | 50 | 58.3 |
| MO | 42.8 | 44.4 | 53 | 53.8 | 39.3 | 38 | 50.3 | 57.1 |
| MT | 43.7 | 41.7 | 52.7 | 55.4 | 31.5 | 36 | 46.5 | 56.5 |
| NE | 41 | 38 | 54 | 59.8 | 29 | 34 | 56 | 60.3 |
| NV | 50.2 | 52.4 | 47.4 | 45.7 | 45 | 47.9 | 45.8 | 45.5 |
| NH | 49.9 | 52 | 47.9 | 46.4 | 43.3 | 47.6 | 42.7 | 47.2 |
| NJ | 52.3 | 58.3 | 40.5 | 40.6 | 48.7 | 55 | 37 | 41.8 |
| NM | 51.7 | 53 | 41.7 | 42.8 | 45.3 | 48.3 | 40.3 | 40 |
| NY | 60.7 | 63.3 | 34.3 | 35.2 | 50.3 | 58.8 | 31.3 | 37.5 |
| NC | 46.2 | 48.4 | 49.2 | 50.4 | 45.5 | 46.7 | 46.5 | 50.5 |
| ND | 37.3 | 38.7 | 55 | 58.3 | 29 | 27.8 | 47 | 64.1 |
| OH | 50 | 50.7 | 47.1 | 47.7 | 42.3 | 43.5 | 45.8 | 52.1 |
| OK | 33 | 33.2 | 59 | 66.8 | 32.5 | 28.9 | 52 | 65.3 |
| OR | 47.7 | 54.2 | 41.7 | 42.2 | 44 | 51.7 | 36 | 41.1 |
| PA | 49.4 | 52 | 45.6 | 46.6 | 46.2 | 47.6 | 44.3 | 48.8 |
| RI | 54 | 62.7 | 33 | 35.2 | 48 | 55.4 | 36.5 | 39.8 |
| SC | 45 | 44.1 | 42 | 54.6 | 38 | 40.8 | 44.2 | 54.9 |
| SD | 41 | 39.9 | 53 | 57.9 | 36.3 | 31.7 | 47 | 61.5 |
| TN | 34 | 39.1 | 59 | 59.5 | 35.5 | 34.9 | 47 | 61.1 |
| TX | 39 | 41.4 | 55.7 | 57.2 | 38 | 43.4 | 50 | 52.6 |
| UT | 25 | 24.8 | 70 | 72.8 | 27 | 27.8 | 37.4 | 45.9 |
| VT | 62 | 66.6 | 25 | 31 | 45.2 | 61.1 | 20.5 | 32.6 |
| VA | 48 | 51.2 | 47.7 | 47.3 | 47.3 | 49.9 | 42.3 | 45 |
| WA | 53.5 | 56.2 | 43 | 41.3 | 50.3 | 54.4 | 36 | 38.2 |
| WV | 33 | 35.5 | 54 | 62.3 | 30.5 | 26.5 | 53 | 68.7 |
| WI | 50.4 | 52.8 | 46.2 | 45.9 | 46.8 | 47.9 | 40.3 | 46.9 |
| WY | 26.5 | 28 | 73.5 | 69.3 | 20 | 22.5 | 56.3 | 70 |

The vast majority of the data set forth in Tables A and B were obtained from the RealClearPolitics™ web site owned by RealClearInvestors™ and Credit Media™. These data are available by RealClearPolitics™ for download. There were four states where the RealClearPolitics website did not have polling data. For those states, the polling data were obtained from Washington Post™ for Alabama; Election Projection™ for Hawaii and North Dakota, and 270toWin™ for Wyoming. In the 2012 election Delaware and Alaska did not have polling data and therefore the poll and actual were assumed to be the same.

The states identified in the compression filter Report are not the same as the states identified in the analysis of the toss-up states or battleground states. The geographic regions in the polling error analysis used in this invention has nothing to do with “too close to call” or “evenly split”. If fact many of the states in the filter design of this invention are almost always Republican (i.e. Georgia) or always Democrat (i.e. Virginia). Nor is the size of the electoral votes a factor. New York and California have the highest electoral college votes and they are not included in most of the compression filter Reports, e.g. California and New York together only appeared once out of 45 compression filter Reports. Montana is included in many of the Reports, and it is one of the smallest electoral college vote states. Also, the occurrence frequency signals used in this invention are not based on which candidate won in a particular state. The filter and compression design in this invention are based on voting error data converted into standard deviation intervals. This filter design is not based on past winning.

There are several terms that have been used in this invention that are well known by those skilled in the art. However, for illustrative purposes, the following provides an alphabetical listing of these topics.

Application Means. An application means includes any device or method capable of applying a set of instructions to data and/or digital signals. This is typically logic circuits that turn on or off depending upon coding commands from a program. Such means are well within the experience of those skilled in the art. However, sequence of steps and the combination of steps as set forth in detail hereinbefore are unique and produce the unexpected results, a few examples of which are shown in FIG. 12.

Average Polling Error. The average polling error is typically the arithmetic average, i.e. the sum of the errors divided by the number of the errors. However, other types of averages may be used, such as a median value, a trimmed mean, particularly when there are a high and low a value that are extremely divergent from the other values, a weighted average, etc.

Candidates. In a political election in the United States there are candidates from two main political parties. Data on the minor party candidates that have no reasonable chance of winning the national election are not directly used. They are considered indirectly by the vote percentages applicable to the main candidates from each state. The individual candidates change from election to election, but the political parties do not. Therefore, the error analysis methodology uses past election cycles applicable to the two parties, i.e. Democrat or Republican, and not to the individually named candidates. The use of the word candidate refers to the Democrat or Republican nominee. It is not intended to be restricted to a specific individual. The same is true for elections in state and foreign countries.

Computer. The term Computer encompasses a wide range of devices and processors. Generally, it is any electronic device used for storing, retrieving or processing data. Examples of computers include mainframe, mini, micro, desktops, laptops, tablets, smart phones, and the like. In the olden-days computers were analog devices using vacuum tubes. The discovery of the transistors changed how computers operate into a digital world using signals based on binary type codes.

Current or New Polling Data. The current or new polling data are polling data for an election that has not occurred. This current data will be used to project a winner or most probable winner of the next or upcoming election. This is the type of data that will be filtered and compressed by the compression filter.

Electronic Compression Filter. The electronic compression filter is a collection of logic circuits in a computer that generates signals in accordance with the flow chart shown in FIG. 1. These compression filter signals have value in and of itself without the further of processing of current polling data to project a winner. For example, the compression filter may generate a report identifying those geographic areas that need to be polled thereby eliminating the necessity of polling every geographic region. For example, in FIG. 10 the compression filter Report lists 18 states in the 2016 past polling and voting data that will be determinative of the election in 2020. This eliminates performing 2020 polls in the other 32 states. In FIG. 9 for two periods 2012-2016 there are 8 states listed, which would eliminate polling in the other 42 states. In FIG. 11 there are 10 states listed for the 2012 & 2016 periods.

Electronic Compression Filter Settings. Any compression and filter setting can be used to reduce the file size and processing time for the polling data. The filter may be set at Whole or Half at the option of the operator. Default values can also be set. In general, the Whole setting produces more geographic regions (e.g. states) than a “Half” setting. For example, in FIG. 8 for 2008 using a Whole setting there are 16 states listed with a compression priority code of 2, whereas using the Half settings for the same settings there are only 3 states listed. See FIG. 10. Although 3 states could be used it is not a preferred embodiment because there are too few states listed.

The filter selection for a standard deviation value of 0 is the preferred setting when the Whole rounding has been selected. The wider the range of standard deviation values, larger number of geographic regions will be identified. With respect to the Half rounding, the filter selection will normally be 0. If those settings produce too few states then an additional value of ±0.5 may be added. It is also possible to use standard deviation value of 0 plus −0.5 or 0 plus +0.5. Values beyond ±0.5 are not recommended, but can be used.

The filter selection also can be selected for a single period or multiple periods. A single period is one election year, i.e. 2004, 2008, 2012, 2016 etc. A multiple period is more than one election period. FIG. 12 shows success rates for single election years, double election years and triple election years. Any of these, and others, can be used to produce a compression filter report or a projection signals for the next or following election. It is preferred to use the past data signals closest in time to the upcoming election. For example, it would be preferred to use 2012 past data to predict the 2016 election. Using 2004 past data to predict the 2020 election can be done, but not recommended. For example, in FIG. 8 the 2004 data using a Whole setting and a priority code of 2 projected a Tie for the 2016 election, but in FIG. 9 the 2004 data using a Half setting and a priority code of 1 and 2 correctly projected a Trump victory as did the 2004 data using a Half setting and a standard deviation value of 0±0.5 correctly projected Trump. It is recommended that 2004 past data be used to project the 2008 winner, the 2008 past data be used to project the 2012 winner, the 2012 past data be used to project the 2016 winner, and the 2016 past data be used to project the 2020 winner. The same is true with multiple years, it is preferred to use the multiple year period that is closest in time to the election. It is likewise preferred to use consecutive multiple years, i.e. 2004 with 2008, or 2008 with 2012, or 2012 with 2016. However, using 2004 with 2012 data can be used successfully, it is less preferred. The same is true for triple year selections.

Compression settings are made with the priority codes. The priority code number depends upon the number of times the same state or geographic region are repeated. In the preferred embodiment, the highest priority codes are used first, i.e. preferentially. For example, if 11 geographic regions have a priority code of 5, those geographic regions are preferably used before any lower priority code is applied. But, if there are too few geographic regions with the highest priority code then the priority code selection should be broadened to include one or more lower codes. Also, it is preferred to use all of the geographic regions that have the selected priority code or codes. For example, if there are 11 geographic regions with a priority code of 4 and 10 geographic regions with a priority code of 3, it is preferred to use all 10 geographic regions with priority code of 4 before using those geographic regions with a priority code of 3. It is also preferred to use all geographic regions that have the selected priority codes rather than use only a portion of those states with the same priority code.

The preferred compression priority codes are those that will produce at least 7 and more preferably at least 9 geographic regions (e.g. states) with the selected priority code or codes. It is also preferred to use odd numbers rather than even numbers, particularly with numbers less than 10, i.e. 7 is preferred over 6 and 9 is preferred over 8. It is also preferred to keep the number of geographic regions at 25 or below. As such, priority codes that produce 30 geographic regions or more, for example, should be raised to a higher range of priority codes to reduce the number of geographic regions. Alternatively, changes in the Whole or Half filter settings, or the range of the standard deviation values, or changes in the periods or multiple periods, may be made to produce the preferred numbers of geographic regions.

In a preferred embodiment, multiple compression and filter settings are used to generate multiple reports and projections. This way any tie or anomaly can be eliminated by averaging multiple projections. In order to run multiple projections, it would be preferred to obtain current polling data from those states that are common to the multiple Compression Filter Reports. For example, there are 18 states shown in the FIG. 10 for 2016. If the multiple year period shown in FIG. 9 was to be used along with those used in FIG. 10, then 4 more states would have to be added to the 18. That is, there are 4 states that were not identified in the 2016 single period report, i.e. Georgia, Indiana, North Carolina, and Pennsylvania. If a third report as shown in FIG. 11 were to be used then two additional states (Maryland and Michigan) would need to be included in the current polling data. Hence, to perform all three compression and filter settings a total of 24 states would need to be polled.

Database. The term Database in its general definition is a structed set of data held in a computer. Normally data is organized in rows, columns, and tables and indexed for retrieving information. Most databases are relational i.e. designed to recognize relationships between data. The Databases referred to in this invention are relational in that they maintain a relationship between data.

Geographic Areas. The geographic areas need not be states. It could apply to cities, regions, or any other geographic bounded area. However, the voting or success data must be rationally connected the polling data within the same geographic regions. In US Presidential elections, using all 50 states would yield the most accurate results. It is recognized that polling data from all 50 states are not always available, particularly from some of the less populated states. This invention remains applicable as long as at least 30 states, preferably at least 35 and more preferably more than 40 states are used. The geographic regions may also be selected by random sampling, particularly if the number of geographic regions are large.

Input Means. There are various types of data that are received and entered into the computer processing aspects of this case. A device or method for receiving data is broadly an input means. This data may be received via digital electronic files, i.e. signals in various file formats, or by an incoming individual stream of data signals. For example, data from different geographic areas, from different political party candidates, from different pollsters, etc. may be received at different time periods. The data may be also manually entered by typing into a keyboard which converts the keystrokes into digital signals. Any method whereby the data is entered into the computer in a digital format would be included.

Logic Means. Generally, logic is a system within a computer guided by software so as to perform specified tasks. As used in this invention, any mathematical manipulation of data by a digital computer circuit constitutes a logic means. There are many mathematical manipulations used in this invention which are included in logic means. Although a logic circuit is well known to those skilled in the art, the unique combination and sequence of these logic circuits are not, i.e. generating the polling errors, occurrence events, occurrence frequencies, standard deviation intervals, compression priority settings, etc.

Other Polling Applications. The best mode in this invention relates to compression and filtering of polling data from the top two candidates in national presidential elections. However, this invention is in other polling schemes such as products and services. A simple example would be past polling data relating to over-the-counter medicines. Success data relating to each of those medicines may be in a form that is indicative of success, i.e. sales volume, profit, etc. as long as it is rationally connected to the polling data. The products and services could also be subcategorized by age, sex, occupation, diseases, drug users, etc. The past polling data and past success data would go into a polling error analysis to test how the product or service is performing in relation to a new or current poll. An example of services would include customer satisfaction polls.

Past Polling Data. Past polling data are polling data that has been taken previously during an election cycle. Past polling data closest in time to the applicable voting data is preferred. Although past polling data nearest in time to the voting data is preferred, it is not critical as long as a relationship exits. The polling error analysis method takes into account a possible higher polling error that may be due to a lapse of time. This is taken into account by subtracting the average polling error from individual polling errors. The past polling data must maintain a relationship between and the time period, the political parties, e.g. Democrat or Republication, and the geographic regions, e.g. states. In a preferred embodiment, the source of polling data is also relationally maintained. The past polling data may also be the average of many polls.

Although obtaining past polling data from all 50 states would yield the most accurate results when applied to a national presidential election, it is recognized that such polling data are not always available from some of the smaller populated or remote states. This invention remains applicable as long as at least 30 states, preferably at least 35 states and more preferably at least 40 states have past polling data.

Past Success Data. The algorisms used in this invention to find, filter and compress the data signals are based on a polling error analysis methodology. The past success data relating to national elections would be voting data. These data are available from the various governmental sources i.e. States, US Government, or foreign governments. These data are also available from all mainstream news sources as well as most pollster via the internet. The voting or success data must be related to the applicable polling data for the same geographic region and same time period. As an example, past polling data applicable to New York state should be compared with the voting results for New York state in the same election period. Voting data must also be compared to the polling data applicable to the same political party.

Pollsters. The accuracy of the pollster or polling company used to generate the past polling data is important, but not essential. Pollster accuracy varies greatly and most, if not all, carry a bias component. This was the subject of a pollster accuracy study done by FiveThirtyEight™ involving 370 companies. This study was done by Nate Silver in Nov. 10, 2012 entitled Which Polls Fared Best (and worst) in the 2012 Presidential Race, FiveThirtyEight™, ESPN Inc. Bristol Conn. This study is available for download from FiveThirtyEight™ website. The polling error analysis method takes into account some variations in polling errors. The type of polling methodology used by the pollsters is likewise important, but not essential. In a preferred embodiment, pollsters having some experience with a good reputation for accuracy are recommended. Those pollsters are generally identified in the pollster accuracy study referenced above. The polling methodology is likewise important, but not essential. The preferred methodology has a probability or statistical based analysis. Polling methodologies such as straw polls or volunteer polls are less accurate, produce the highest variability in errors, and not recommended. The pollsters that generated the past polling data and the pollsters that generated the current polling data are preferably the same, but not essential.

Report Means. A report means includes any device or method capable of expressing results. Such means are well within the experience of those skilled in the art. Normally this would be accomplished by a visual display or by a printed output.

Standard Deviation Polling Error. The standard deviation is a measure of the data point deviations from its mean. In general, it is the square root of the sum of the square of the deviation from the mean divided by the number of data points minus 1. This calculation is common and well known by those skilled in the art.

Unnecessary Data. For purposes of this invention the term “unnecessary data” is that data which are not required to accomplish the objective or results. Unnecessary data may include useful data or even data that may improve a particular result.

The invention claimed is:

1. An electronic compression filtering system that compresses polling data and improves computer performance used in processing the compressed polling data comprising:
a digital computer with an accessible relational database;
a first input means for receiving past polling data applicable to the Republican and Democrat candidates in an election from at least one past polling period from multiple geographic regions;
a second input means for receiving past voting data related to the polling data received in said first input means;
a first logic means for generating polling error data from said past polling data and said past voting data;
a second logic means for generating rounded occurrence event data from the said polling error data and arranged into standard deviation intervals, said standard deviation intervals rounded to the nearest whole integer or half integer; and said rounded occurrence event data has a standard deviation interval value associated with each geographic region;
a third logic means for generating occurrence frequency data from the rounded occurrence event data; wherein said standard deviation interval value is selected from one of the following:
(i) 0;
(ii) 0 and one or more of the following values: −1 and +1, when whole integer rounding is used, and
(iii) 0 and one or more of the following: values: −0.5, +0.5, −1 and +1, when half integer rounding is used; and
wherein said occurrence frequency data maintains a relationship to the geographic regions, the Republican and Democrat candidates, and each past polling period;
a fourth logic means for combining said occurrence frequency data applicable to the geographic regions for the Republican and Democrat candidates for at least one past polling period and for generating electronic compression filter data that are related to a limited number of geographic regions and comprising a reduction of at least 30 to 90 percent of the total number of geographic regions; and
an application means for processing said electronic compression filter data by performing at least one of the following steps:
(a) a report generation means for generating a report identifying said limited number of geographic regions; and
(b) a projection processing means for applying said limited number of geographic regions to polling data applicable to an upcoming election comprising:
an input means for receiving polling data applicable to an upcoming election;
a means for processing said polling data applicable to an upcoming election as reduced by said limited number of geographic regions; and
a means for displaying a projected winner of said upcoming election.

2. The system of claim 1 wherein said occurrence frequency data have a standard deviation interval value of 0.

3. The system of claim 2 wherein said occurrence event data are rounded to the nearest whole integer.

4. The system of claim 1 wherein said occurrence event data are rounded to the nearest half integer.

5. The system of claim 1 wherein a priority code is assigned to the electronic compression filter data and equal to the number of times each geographic region occurs, and said application means uses said projection processing set forth under step (b).

6. The system of claim 5 wherein each geographic region with an assigned priority code has the highest priority code, and said application means uses said projection processing set forth under step (b).

7. (canceled)

8. (canceled)

9. A method of filtering and compressing polling data that improves computer performance in processing the compressed polling data comprising:
receiving past polling data applicable to the Republican and Democrat candidates in at least one past election period from multiple geographic regions;
receiving past voting data applicable to said past polling data;
generating polling error data from said past polling data and said past voting data;
generating rounded occurrence event data from the said polling error data and arranged into standard deviation intervals and rounded to the nearest whole integer or half integer; and said rounded occurrence event data has a standard deviation interval value associated with each geographic region;
generating occurrence frequency data from said rounded occurrence event data, wherein said standard deviation interval value is selected from one of the following:
(i) 0 or 0 and one or more of the following values: −1 and +1, when whole integer rounding is used, and
(ii) 0 or 0 and one or more of the following: values: −0.5, +0.5, −1 and +1, when half integer rounding is used, and wherein said occurrence frequency data maintain a relationship to the geographic regions applicable to the Republican and Democrat candidates and to each past polling period;
generating electronic compression filter data from the occurrence frequency data by combining the geographic regions for the Republican and Democrat candidates for at least one past polling period, wherein said electronic compression filter data are related to a limited number of geographic regions and comprising a reduction of at least 30 to 90 percent of the total number of geographic regions; and
applying said electronic compression filter data by performing at least one additional step selected from the group consisting of:
(a) generating a report identifying said limited number of geographic regions included within the compression filter data; and
(b) projecting a winner in an upcoming election by:
receiving polling data applicable to an upcoming election;
processing said polling data applicable to said upcoming election as reduced by said limited number of geographic regions; and
displaying a projected winner of said upcoming election.

10. The method of claim 9 wherein said occurrence frequency data are further filtered by using a standard deviation interval value of 0.

11. The method of claim 9 wherein said occurrence event data are rounded to the nearest whole integer.

12. The method of claim 9 wherein said occurrence event data are rounded to the nearest half integer.

13. The method of claim 9 wherein the geographic regions included within the compression filter data are assigned a priority code equal to the number of times each geographic region occurs and said additional step uses step (b).

14. The method of claim 9 wherein only those geographic regions with the highest priority codes are selected and said additional step uses step (b).

15. A method of filtering and compressing polling data in a national United States election that improves computer performance in processing the compressed polling data comprising:
receiving past polling data applicable to the Republican and Democrat candidates in at least one past polling period in a United States presidential election;
receiving past voting data related to said past polling data;
generating polling error data from said past polling data and said past voting data;
generating rounded occurrence event data from said polling error data and arranged into standard deviation intervals, said standard deviation intervals being rounded to the nearest whole integer or half integer; and said rounded occurrence event data has a standard deviation interval value associated with each geographic region;
generating occurrence frequency data from said rounded occurrence event data wherein said occurrence frequency data maintain a relationship to the States applicable to the Republican and Democratic candidates and to each past polling period, and wherein said standard deviation interval value is selected from one of the following:
(i) 0;
(ii) 0 and one or more of the following values: −1 and +1, when whole integer rounding is used, and
(iii) 0 and one or more of the following: values: −0.5, +0.5, −1 and +1, when half integer rounding is used; and
generating compression filter data from the occurrence frequency by combining the States for the Republican and Democrat candidates for at least one past polling period and resulting in States being repeated;
each of said States are assigned a priority code equal to the number of times each State occurs; and
at least one priority code is selected resulting in a limited number of States of no more than 25 nor less than 8 States included within said compression filter data; and
subjecting said compression filter data to at least one additional step selected from the group consisting of:
(a) generating a report identifying said limited number of States included within the compression filter data; and
(b) receiving polling data for an upcoming US presidential election for the Republican and Democrat candidates,
processing said polling data for said upcoming US presidential election as reduced by said limited number of States included within said compression filter data; and
displaying a projected winner of said upcoming US presidential election.

16. The method of claim 15 wherein said occurrence event data are rounded to the nearest standard deviation interval whole integer and the selected standard deviation interval value is 0.

17. The method of claim 15 wherein said additional step uses step (b), said occurrence event data are rounded to the nearest standard deviation interval half integer, and the selected standard deviation interval value is selected from one of the following values:
0;
0 plus −0.5;
0 plus +0.5; and
0 plus −0.5 plus +0.5

18. The method of claim 15 wherein the past polling data are from the election period immediately prior to a current election cycle and said additional step uses step (b).

19. The method of claim 15 wherein said additional step uses step (b) and the past polling data are from multiple election periods selected from one of the following:
two election periods closest in time to an upcoming election;
two election periods within 4 election periods closest in time to an upcoming election;
three election periods closest in time to an upcoming election; and
three election periods within 4 election periods closest in time to an upcoming election.

20. The method of claim 15 wherein said additional step uses step (b) and multiple different filter and compression setting are selected.
